(19) United States
(12) Patent Application Publication
(10) Pub. No.: US 2025/0185373 A1
(43) Pub. Date: Jun. 5, 2025

(54) ARRAY SUBSTRATE AND DISPLAY DEVICE INCLUDING THE SAME

(71) Applicant: E Ink Holdings Inc., HSINCHU (TW)

(72) Inventors: Hsien-Yi HSIAO, HSINCHU (TW); Pang-Yi LIU, HSINCHU (TW); Ming-Kai CHUANG, HSINCHU (TW); Lih-Hsiung CHAN, HSINCHU (TW)

(21) Appl. No.: 18/953,026

(22) Filed: Nov. 19, 2024

(30) Foreign Application Priority Data
Dec. 1, 2023 (TW) 112146932

(51) Int. Cl. H01L 27/12

(52) U.S. Cl. CPC H10D 86/60; H10D 86/441

(57) ABSTRACT

An array substrate has a geometric center and a virtual median line passing through the geometric center, and includes a substrate, a first metal layer, a second metal layer, active elements and a shielding pattern layer. The first metal layer is disposed on the substrate and includes first signal lines. The second metal layer is disposed on the first metal layer and includes second signal lines. The active elements are disposed on the substrate. Each active element is electrically connected to one of the first signal lines and one of the second signal lines and includes a channel layer. The shielding pattern layer is disposed between the first metal layer and the second metal layer, overlaps the virtual median line on the normal line of the substrate, and is formed by patterning the same layer as the channel layers.

### RELATED APPLICATIONS

This application claims priority to Taiwan Application Serial Number 112146932, filed Dec. 1, 2023, which is herein incorporated by reference in its entirety.

### BACKGROUND

### Field of Invention

The present disclosure relates to an array substrate and a display device including the same. More particularly, the present disclosure relates to an array substrate including a shielding pattern layer.

### Description of Related Art

Display devices have been widely used in various forms of electronic products. In one type of display device, some layers of the array substrate are formed by using half tone mask for exposure development and then etching, in order to reduce the number of masks and simplify the process. However, when the masks are spliced together for exposure development due to the size requirements of the display device, the photoresist located at the mask splicing area may be removed after repeated exposures, resulting in etching breaks in the signal lines under the photoresist located at the mask splicing area, which in turn leads to a decrease in yield.

### SUMMARY

At least one embodiment of the present disclosure provides an array substrate, which includes a shielding pattern layer that is patterned together with the channel layers of the active elements, and the shielding pattern layer overlaps a virtual median line that passes through the geometric center of the array substrate. Therefore, while reducing the number of masks and simplifying the process by splicing the halftone masks, the signal lines located at the mask splicing area can be protected from etching breaks, thus maintaining the yield.

Another embodiment of the present disclosure provides a display device, which includes the abovementioned array substrate.

The array substrate according to at least one embodiment of the present disclosure has a geometric center and a virtual median line passing through the geometric center and extending in a first direction, and includes a substrate, a first metal layer, a second metal layer, a plurality of active elements, and a shielding pattern layer. The virtual median line is perpendicular to a normal line of the substrate. The first metal layer is disposed on the substrate and including a plurality of first signal lines. The second metal layer is disposed on the first metal layer and including a plurality of second signal lines. The active elements are disposed on the substrate, where each of the active elements is electrically connected to one of the first signal lines and one of the second signal lines, and includes a channel layer. The shielding pattern layer is disposed between the first metal layer and the second metal layer, where the shielding pattern layer overlaps the virtual median line on the normal line of the substrate and is formed by patterning the same layer as the channel layers.

The display device according to at least one embodiment of the present disclosure includes an array substrate and a display medium disposed on the array substrate. The array substrate has a geometric center and a virtual median line passing through the geometric center and extending in a first direction, and includes a substrate, a first metal layer, a second metal layer, a plurality of active elements, and a shielding pattern layer. The virtual median line is perpendicular to a normal line of the substrate. The first metal layer is disposed on the substrate and including a plurality of first signal lines. The second metal layer is disposed on the first metal layer and including a plurality of second signal lines. The active elements are disposed on the substrate, where each of the active elements is electrically connected to one of the first signal lines and one of the second signal lines, and includes a channel layer. The shielding pattern layer is disposed between the first metal layer and the second metal layer, where the shielding pattern layer overlaps the virtual median line on the normal line of the substrate and is formed by patterning the same layer as the channel layers.

It is to be understood that both the foregoing general description and the following detailed description are by examples, and are intended to provide further explanation of the present disclosure as claimed.

### BRIEF DESCRIPTION OF THE DRAWINGS

The present disclosure can be more fully understood by reading the following detailed description of the embodiment, with reference made to the accompanying drawings as follows:

FIG. 1 is a schematic top view of an array substrate according to at least one embodiment of the present disclosure.

FIG. 2A is an enlarged schematic view of region A in FIG. 1.

FIG. 2B is an enlarged schematic view of region B in FIG. 1.

FIG. 2C is an enlarged schematic view of region C in FIG. 1.

FIG. 3 is a schematic cross-sectional view taken along line a-a′ of FIG. 2A.

FIG. 4A is an enlarged schematic view of region D in FIG. 1.

FIG. 4B is an enlarged schematic view of region E in FIG. 1.

FIG. 5 is an enlarged schematic view of region F in FIG. 1.

FIG. 6 is a schematic cross-sectional view taken along line b-b′ of FIG. 5.

FIG. 7 is a schematic cross-sectional view of a display device according to at least one embodiment of the present disclosure.

### DETAILED DESCRIPTION

The embodiments of the present disclosure are discussed in detail below. It will be appreciated, however, that the embodiments provide many applicable concepts which may be implemented in a wide variety of specific contexts. The discussed and disclosed embodiments are for illustrative purposes only and are not intended to limit the scope of patent applications in this case.

In the following description, in order to clearly present the technical features of the present disclosure, the dimensions of elements in the drawings will be enlarged in unequal proportions. Therefore, the description and explanation of the following embodiments are not limited to the sizes and shapes presented by the elements in the drawings, but should cover the sizes, shapes, and deviations of the two due to actual manufacturing processes and/or tolerances. For example, the flat surface shown in the drawings may have rough and/or non-linear characteristics, and the acute angle shown in the drawings may be round. Therefore, the elements presented in the drawings in this case are mainly for illustration, and are not intended to accurately depict the actual shape of the elements, nor are they intended to limit the scope of patent applications in this case.

Furthermore, the words “about”, “approximately” or “substantially” used in the present disclosure not only cover the clearly stated numerical values and numerical ranges, but also cover those that can be understood by a person with ordinary knowledge in the technical field to which the present disclosure belongs. The permissible deviation range can be determined by the error generated during measurement, and the error is caused, for example, by limitations of the measurement system or process conditions. For example, two objects (such as the plane or traces of a substrate) are “substantially parallel” or “substantially perpendicular,” where “substantially parallel” and “substantially perpendicular,” respectively, mean that parallelism and perpendicularity between the two objects can include non-parallelism and non-perpendicularity caused by permissible deviation ranges.

In addition, “about” may mean within one or more standard deviations of the above values, such as within +30%, +20%, +10%, or +5%. Such words as “about”, “approximately”, or “substantially” as appearing in the present disclosure may be used to select an acceptable range of deviation or standard deviation according to optical properties, etching properties, mechanical properties, or other properties, rather than applying all of the above optical properties, etching properties, mechanical properties, and other properties with a single standard deviation.

The spatial relative terms used in the present disclosure, such as “below,” “under,” “above,” “on,” and the like, are intended to facilitate the recitation of a relative relationship between one element or feature and another as depicted in the drawings. The true meaning of these spatial relative terms includes other orientations. For example, the relationship between one element and another may change from “below” and “under” to “above” and “on” when the drawing is turned 180 degrees up or down. In addition, spatially relative descriptions used in the present disclosure should be interpreted in the same manner.

It should be understood that while the present disclosure may use terms such as “first”, “second”, “third” to describe various elements or features, these elements or features should not be limited by these terms. These terms are primarily used to distinguish one element from another, or one feature from another. In addition, the term “or” as used in the present disclosure may include, as appropriate, any one or a combination of the listed items in association.

Moreover, the present disclosure may be implemented or applied in various other specific embodiments, and the details of the present disclosure may be combined, modified, and altered in various embodiments based on different viewpoints and applications, without departing from the idea of the present disclosure.

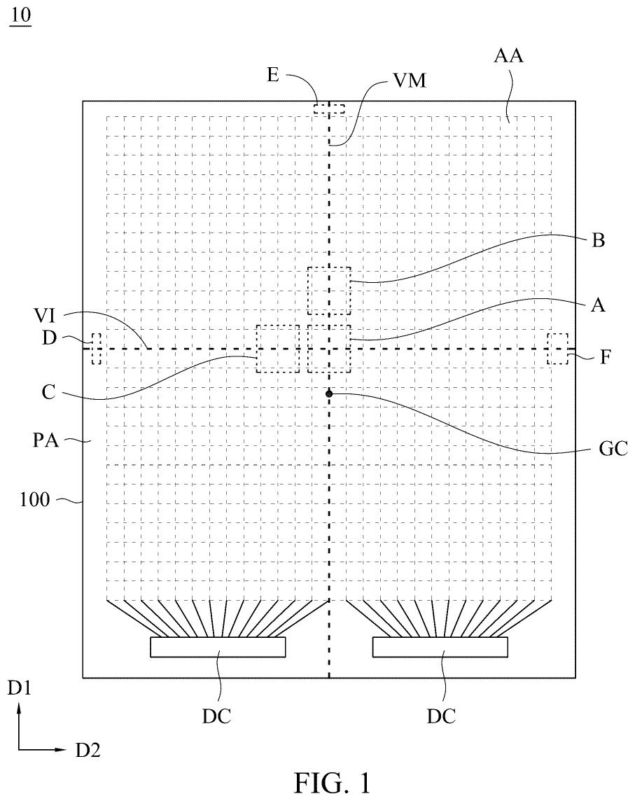

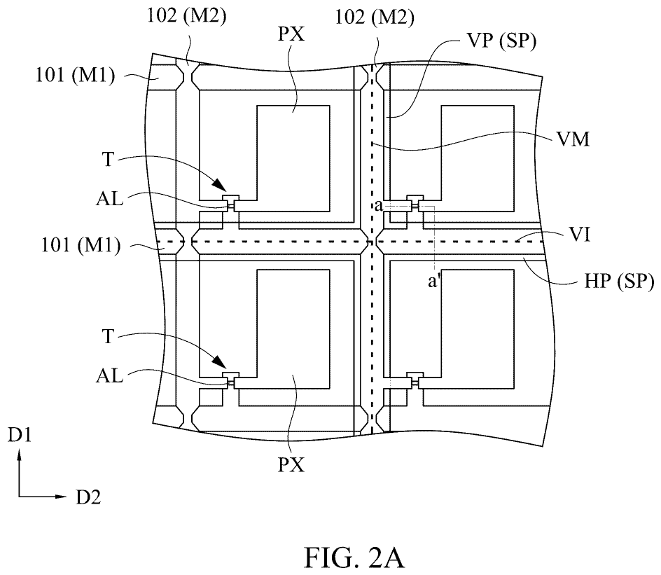

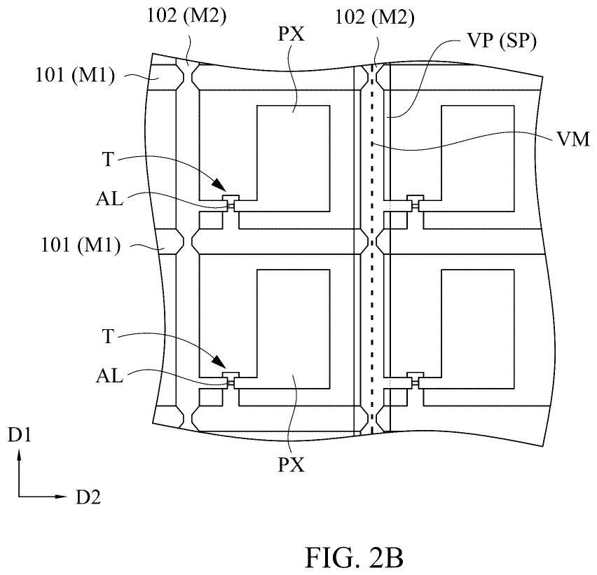

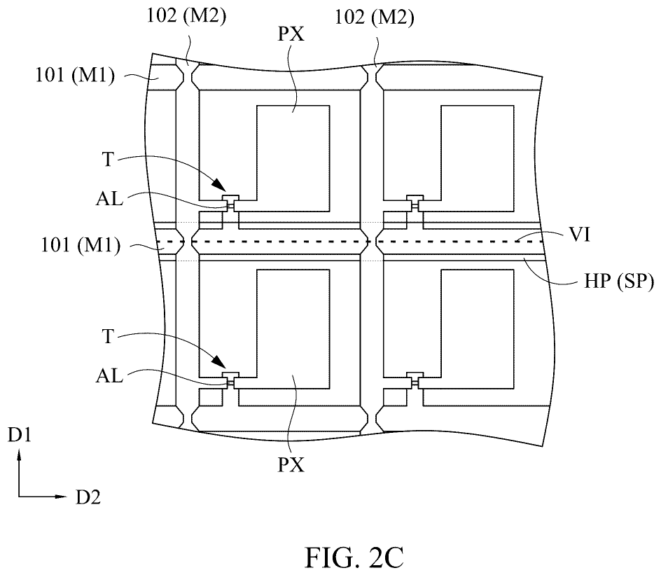

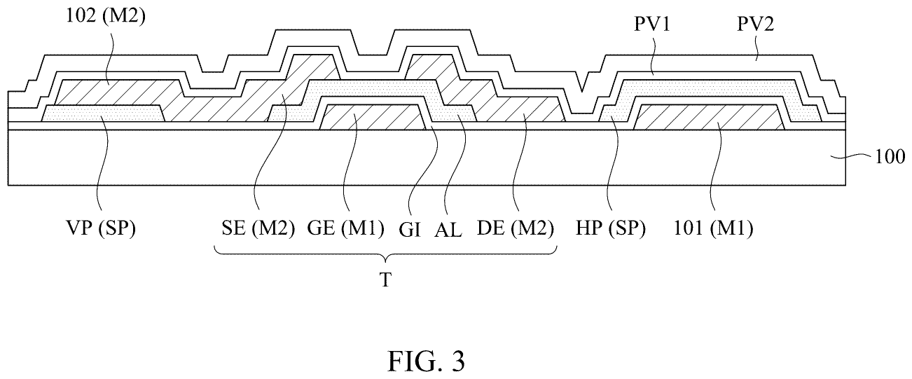

FIG. 1 is a schematic top view of an array substrate according to at least one embodiment of the present disclosure. FIG. 2A is an enlarged schematic view of region A in FIG. 1. FIG. 3 is a schematic cross-sectional view taken along line a-a′ of FIG. 2A. Referring to FIG. 1 and FIG. 2A. The array substrate 10 has a geometric center GC and a virtual median line VM passing through the geometric center GC and extending in a first direction D1. The array substrate 10 includes a substrate 100, a first metal layer M1, and a second metal layer M2, a plurality of active elements T and a shielding pattern layer SP. The virtual median line VM is perpendicular to the normal line of the substrate 100. That is, the virtual median line VM is parallel to the surface of the substrate 100.

Referring to FIG. 2A and FIG. 3, the first metal layer M1 is disposed on the substrate 100 and includes a plurality of first signal lines 101. The second metal layer M2 is disposed on the first metal layer M1 and includes a plurality of second signal lines 102. The active elements T are disposed on the substrate 100. Each active element T is electrically connected to one of the first signal lines 101 and one of the second signal lines 102, and includes a channel layer AL. The shielding pattern layer SP is disposed between the first metal layer M1 and the second metal layer M2, overlaps the virtual median line VM on the normal line of the substrate 100, and is formed by patterning the same layer as the channel layers AL. That is, the shielding pattern layer SP and the channel layers AL are made of the same material and formed by the same process.

By disposing the shielding pattern layer that is patterned together with the channel layers of the active elements, and the shielding pattern layer overlaps the virtual median line that passes through the geometric center of the array substrate. Therefore, while reducing the number of masks and simplifying the process by splicing the halftone masks, the signal lines located at the mask splicing area can be protected from etching breaks, thus maintaining the yield.

Referring to FIG. 2A and FIG. 3. As shown in FIG. 2A, the first signal lines 101 are arranged at intervals in the first direction D1 and extend in a second direction D2, and the second signal lines 102 are arranged at intervals in the second direction D2 and extend in the first direction D1. The array substrate 10 further includes a plurality of pixel electrodes PX, and each pixel electrode PX is electrically connected to one of the active elements T. As shown in FIG. 3, each active element T further includes a gate GE, a gate insulating layer GI, a source SE, and a drain DE. The gate GE is disposed on the substrate 100, the gate insulating layer GI is disposed on the gate GE, the channel layer AL is disposed on the gate insulating layer GI, and the source SE and the drain DE are disposed on the channel layer AL. The array substrate 10 further includes a first insulating layer PV1 disposed on the source SE and the drain DE, and a second insulating layer PV2 disposed on the first insulating layer PV1.

In this embodiment, the active element T is a bottom gate type thin film transistor. However, the present disclosure is not limited thereto, and in other embodiments, the active element T may be a top gate type thin film transistor, a vertical channel type thin film transistor, other suitable forms of thin film transistors, or other kinds of active elements.

As shown in FIG. 3, the first metal layer M1 further includes the gate GE, where the gate GE and the first signal lines 101 are formed by patterning the same layer. The second metal layer M2 further includes the source SE and the drain DE, where the source SE and the drain DE and the second signal lines 102 are formed by patterning the same layer. That is, the gate GE and the first signal lines 101 are made of the same material and formed by the same process, and the source SE, the drain electrode DE and the second signal lines 102 are made of the same material and formed by the same process.

In some embodiments, the first signal lines 101 may be scan lines, and the second signal lines 102 may be data lines. However, the elements included in the first metal layer M1 and the second metal layer M2 are not limited to the above-mentioned embodiments. For example, the first metal layer M1 may include the second signal lines 102, the source SE and the drain DE, and the second metal layer M2 may include the first signal lines 101 and the gate GE.

In some embodiments, the material of the substrate 100 may include quartz, glass, polymer materials, or other suitable materials. In some embodiments, a deposition process, an inkjet process, a printing process, a coating process, a photolithography etching process and/or other appropriate processes may be used to form the first metal layer M1, the second metal layer M2 and the pixel electrodes PX, the first insulating layer PV1 and the second insulating layer PV2.

In some embodiments, the first metal layer M1 and the second metal layer M2 may include metals with good conductivity, such as aluminum, molybdenum, titanium, copper and other metals. In some embodiments, the materials of the channel layers AL and the shielding pattern layer SP may include semiconductor materials, such as silicon semiconductor materials (for example, polycrystalline silicon, amorphous silicon, etc.), oxide semiconductor materials, organic semiconductor materials, other appropriate materials, or single layer, multiple layers or combination of the aforementioned materials. In some embodiments, the materials of the pixel electrodes PX may include opaque conductive materials, transparent conductive materials, or combinations thereof. The opaque conductive materials can be, for example, molybdenum, molybdenum nitride, molybdenum niobium, etc., and the transparent conductive materials can be, for example, indium tin oxide, indium zinc oxide, etc.

In some embodiments, the first insulating layer PV1 and the second insulating layer PV2 can be a single-layer structure or a multi-layer stack structure, and the materials of the first insulating layer PV1 and the second insulating layer PV2 may include inorganic insulating materials, organic insulating materials, or combinations thereof. The inorganic insulating materials can be, for example, silicon oxide, silicon nitride, silicon oxynitride, etc., and the organic insulating materials can be, for example, polymethylmethacrylate, siloxane, polyimide, epoxy, photosensitive resin, etc.

FIG. 2B and FIG. 2C are enlarged schematic views of region B and region C in FIG. 1, respectively. Referring to FIG. 1 and FIG. 2A to FIG. 2C, as shown in FIG. 1, the array substrate 10 further has a virtual interlacing line VI intersecting the virtual median line VM and extending in the second direction D2 perpendicular to the first direction D1, where the virtual interlacing line VI is perpendicular to the normal line of the substrate 100. That is, the virtual interlacing line VI is parallel to the surface of the substrate 100 and perpendicular to the virtual median line VM.

As shown in FIG. 2A and FIG. 2B, the shielding pattern layer SP includes a longitudinal part VP extending in the first direction D1, where the longitudinal part VP overlaps the virtual median line VM on the normal line of the substrate 100. As shown in FIG. 2A and FIG. 2C, the shielding pattern layer SP includes a transverse part HP extending in the second direction D2, where the transverse part HP overlaps the virtual interlacing line VI on the normal line of the substrate 100.

In some embodiments, the mask splicing area overlaps the virtual median line VM on the normal line of the substrate 100. In some embodiments, the mask splicing area overlaps the virtual intersecting lines VI on the normal line of the substrate 100. In some embodiments, the shielding pattern layer SP includes a cross pattern.

Furthermore, as shown in FIG. 2A and FIG. 3, the longitudinal part VP overlaps the second signal line 102 on the normal line of the substrate 100, and the transverse part HP overlaps the first signal line 101 on the normal line of the substrate 100. By the aforementioned design, the shielding pattern layer SP can protect the signal lines located below the shielding pattern layer SP from etching breaks. For example, as shown in FIG. 3, the transverse part HP of the shielding pattern layer SP can protect the first signal line 101 located below the transverse part HP.

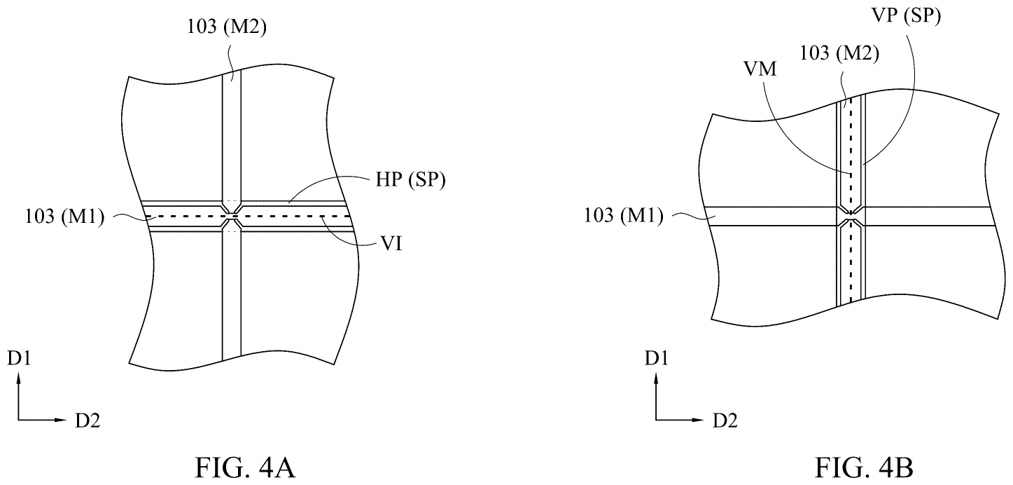

FIG. 4A and FIG. 4B are enlarged schematic views of region D and region E in FIG. 1, respectively. Referring to FIG. 1, FIG. 4A, and FIG. 4B, as shown in FIG. 1, the array substrate 10 further has a display area AA and a peripheral area PA surrounding the display area AA, and further includes a driving circuit DC and wirings (not labeled). The driving circuit DC is disposed in the peripheral area PA, and the wirings are electrically connected to the driving circuit DC and the first signal lines 101 and the second signal lines 102 located in the display area AA. As shown in FIG. 4A and FIG. 4B, one of the first metal layer M1 and the second metal layer M2 may include an external trace 103 located in the peripheral area PA, and the shielding pattern layer SP overlaps with the external trace 103 on the normal line of the substrate 100.

In detail, as shown in FIG. 4A, the external trace 103 of the first metal layer M1 located in the peripheral area PA extends in the second direction D2, and the transverse part HP of the shielding pattern layer SP extending in the second direction D2 overlaps the aforementioned external trace 103 on the normal line of the substrate 100. As shown in FIG. 4B, the external trace 103 of the second metal layer M2 located in the peripheral area PA extends in the first direction D1, and the longitudinal portion VP of the shielding pattern layer SP extending in the first direction D1 overlaps the aforementioned external trace 103 on the normal line of the substrate 100.

In some embodiments, the driving circuit DC may be disposed in at least one chip, but is not limited thereto. In FIG. 1, the driving circuit DC is disposed on the substrate 100, but is not limited thereto. In other embodiments, the driving circuit DC may be disposed on a circuit board and the circuit board is electrically connected to a pad (not shown) disposed on the substrate 100.

In some embodiments, the width of the shielding pattern layer SP may be greater than, less than, and equal to the widths of the first signal line 101, the second signal line 102, and the external trace 103 or combinations of the foregoing width relationships, which may be adjusted depending on the range of the mask splicing area and the width of the signal line located at the mask splicing area. In some embodiments, the shielding pattern layer SP may be a continuous line segment or a discontinuous line segment, which may be adjusted depending on the signal line layout located at the mask splicing area. In some embodiments, the shape of the line segment of the shielding pattern layer SP may be a rectangle, an ellipse, or a circle.

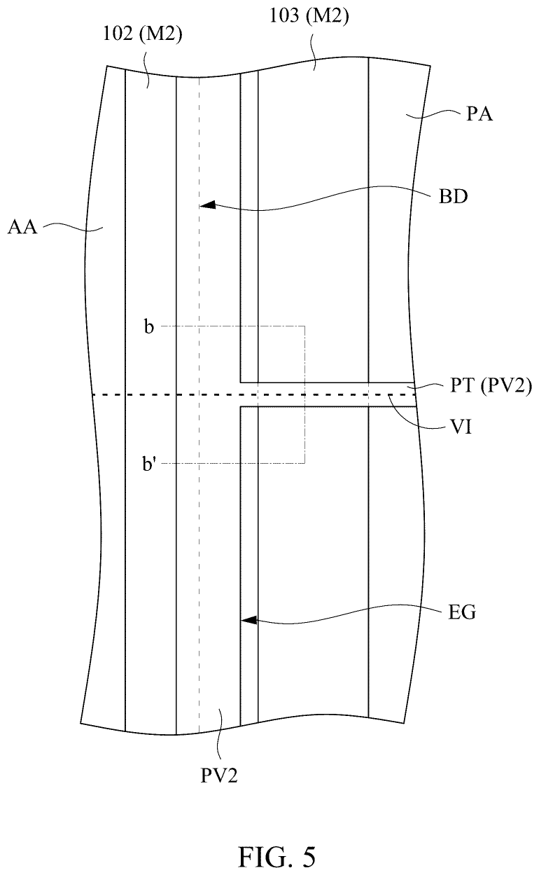

FIG. 5 is an enlarged schematic view of region F in FIG. 1. The second insulating layer PV2 includes a protruding shielding part PT located in the peripheral area PA, and the protruding shielding part PT overlaps one of the virtual median line VM and the virtual interlacing line VI on the normal line of the substrate 100. As shown in FIG. 5, the second insulating layer PV2 has an edge EG parallel to a boundary BD between the display area AA and the peripheral area PA, and includes the protruding shielding part PT protruding from the edge EG, which overlaps the virtual interlacing line VI on the normal line of the substrate 100.

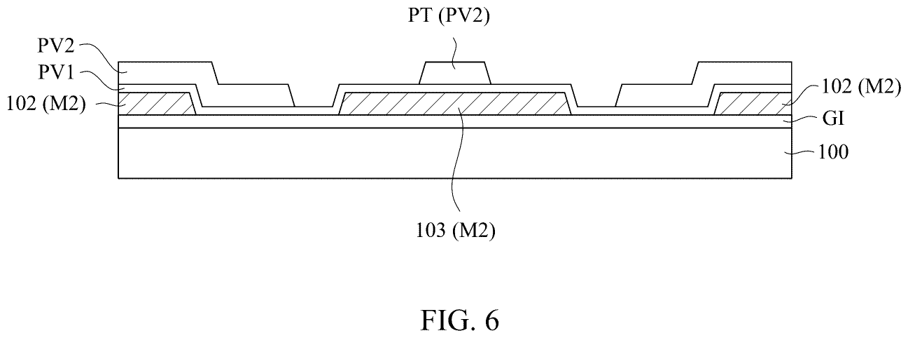

FIG. 6 is a schematic cross-sectional view taken along line b-b′ of FIG. 5. For ease of illustration, FIG. 6 merely shows the substrate 100, the gate insulating layer GI, the second metal layer M2, the first insulating layer PV1 and the second insulating layer PV2. Referring to FIG. 5 and FIG. 6, the protruding shielding part PT of the second insulating layer PV2 overlaps the external trace 103 of the second metal layer M2 located in the peripheral area PA on the normal line of the substrate 100. By the aforementioned design, the protruding shielding part PT can protect the external trace 103 from etching breaks.

In some embodiments, one of the first insulating layer PV1 and the second insulating layer PV2 may include the protruding shielding part, for example, one of the first insulating layer PV1 and the second insulating layer PV2 may include the protruding shielding part, and the other one of the insulating layer PV1 and the second insulating layer PV2 does not include a protruding shielding part, or both the first insulating layer PV1 and the second insulating layer PV2 include the protruding shielding part.

In some embodiments, other metal layer including an external trace located in the peripheral area PA may be disposed between the second metal layer M2 and the second insulating layer PV2. That is, the protruding shielding part of one of the first insulating layer PV1 and the second insulating layer PV2 can be used to protect the aforementioned other metal layer. In addition, the external trace of the array substrate 10 may be formed of the first metal layer M1, and neither the first insulating layer PV1 nor the second insulating layer PV2 may include a protruding shielding part.

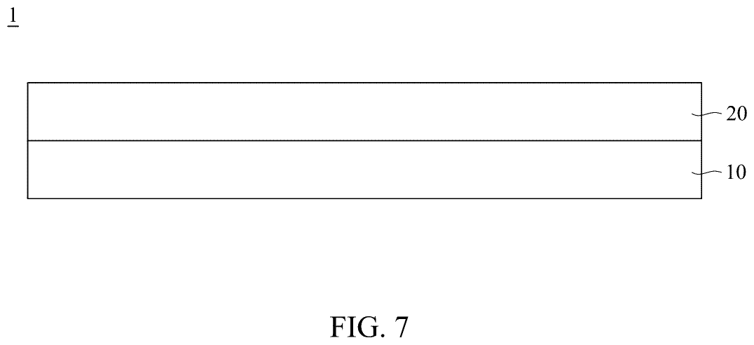

FIG. 7 is a schematic cross-sectional view of a display device according to at least one embodiment of the present disclosure. The display device 1 includes the above-mentioned array substrate 10 and a display medium 20 disposed on the array substrate 10. In some embodiments, the display medium 20 may include a liquid crystal layer, an electrowetting material layer, an electrophoretic layer, a plurality of organic light emitting diodes, or a plurality of light emitting diodes, where the light emitting diodes may be micro light emitting diodes (micro-LEDs, uLEDs) or sub-millimeter light emitting diodes (mini-LEDs). When the display medium 20 is the liquid crystal layer, the substrate 100 may be a light transmitting substrate. When the display medium 20 is the electrowetting material layer, the electrophoretic layer, the organic light emitting diodes, or the light emitting diodes, the substrate 100 may be an opaque circuit substrate.

In summary, the present disclosure provides an array substrate, which includes a shielding pattern layer that is patterned together with the channel layers of the active elements, and the shielding pattern layer overlaps a virtual median line that passes through the geometric center of the array substrate. Therefore, while reducing the number of masks and simplifying the process by splicing the halftone masks, the signal lines located at the mask splicing area can be protected from etching breaks, thus maintaining the yield.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the present disclosure. In view of the foregoing, it is intended that the present disclosure cover modifications and variations of this disclosure provided they fall within the scope of the following claims.

What is claimed is:

1. An array substrate, having a geometric center and a virtual median line passing through the geometric center and extending in a first direction, and comprising:
a substrate, wherein the virtual median line is perpendicular to a normal line of the substrate;
a first metal layer, disposed on the substrate and comprising a plurality of first signal lines;
a second metal layer, disposed on the first metal layer and comprising a plurality of second signal lines;
a plurality of active elements, disposed on the substrate, wherein each of the active elements is electrically connected to one of the first signal lines and one of the second signal lines, and comprises a channel layer; and
a shielding pattern layer, disposed between the first metal layer and the second metal layer, wherein the shielding pattern layer overlaps the virtual median line on the normal line of the substrate and is formed by patterning the same layer as the channel layers.

2. The array substrate of claim 1, wherein the shielding pattern layer comprises a longitudinal part extending in the first direction and overlapping the virtual median line on the normal line of the substrate.

3. The array substrate of claim 2, further having a virtual interlacing line intersecting the virtual median line and extending in a second direction perpendicular to the first direction, and the virtual interlacing line is perpendicular to the normal line of the substrate, wherein the shielding pattern layer comprises a transverse part extending in the second direction and overlapping the virtual interlacing line on the normal line of the substrate.

4. The array substrate of claim 3, wherein the shielding pattern layer comprises a cross pattern.

5. The array substrate of claim 3, wherein the shielding pattern layer overlaps one of the first signal lines and the second signal lines on the normal line of the substrate.

6. The array substrate of claim 3, further having a display area and a peripheral area surrounding the display area, and further comprising an insulating layer, wherein the insulating layer is disposed on the second metal layer and comprises a protruding shielding part located in the peripheral area, and the protruding shielding part overlaps one of the virtual median line and the virtual interlacing line on the normal line of the substrate.

7. The array substrate of claim 6, wherein a material of the insulating layer comprises a photosensitive resin.

8. The array substrate of claim 1, further having a display area and a peripheral area surrounding the display area, wherein one of the first metal layer and the second metal layer comprises an external trace located in the peripheral area, and the shielding pattern layer overlaps the external trace on the normal line of the substrate.

9. The array substrate of claim 1, wherein a material of the shielding pattern layer and the channel layers comprises a semiconductor material.

10. A display device, comprising:
an array substrate, having a geometric center and a virtual median line passing through the geometric center and extending in a first direction, and comprising:
a substrate, wherein the virtual median line is perpendicular to a normal line of the substrate;
a first metal layer, disposed on the substrate and comprising a plurality of first signal lines;
a second metal layer, disposed on the first metal layer and comprising a plurality of second signal lines;
a plurality of active elements, disposed on the substrate, wherein each of the active elements is electrically connected to one of the first signal lines and one of the second signal lines, and comprises a channel layer; and
a shielding pattern layer, disposed between the first metal layer and the second metal layer, wherein the shielding pattern layer overlaps the virtual median line on the normal line of the substrate and is formed by patterning the same layer as the channel layers; and
a display medium, disposed on the array substrate.

11. The display device of claim 10, wherein the display medium comprises an electrophoretic layer.

12. The display device of claim 10, wherein the shielding pattern layer comprises a longitudinal part extending in the first direction and overlapping the virtual median line on the normal line of the substrate.

13. The display device of claim 12, wherein the array substrate further has a virtual interlacing line intersecting the virtual median line and extending in a second direction perpendicular to the first direction, and the virtual interlacing line is perpendicular to the normal line of the substrate, wherein the shielding pattern layer comprises a transverse part extending in the second direction and overlapping the virtual interlacing line on the normal line of the substrate.

14. The display device of claim 13, wherein the shielding pattern layer comprises a cross pattern.

15. The display device of claim 13, wherein the shielding pattern layer overlaps one of the first signal lines and the second signal lines on the normal line of the substrate.

16. The display device of claim 13, wherein the array substrate further has a display area and a peripheral area surrounding the display area, and further comprises an insulating layer, wherein the insulating layer is disposed on the second metal layer and comprises a protruding shielding part located in the peripheral area, and the protruding shielding part overlaps one of the virtual median line and the virtual interlacing line on the normal line of the substrate.

17. The display device of claim 16, wherein a material of the insulating layer comprises a photosensitive resin.

18. The display device of claim 10, wherein the array substrate further has a display area and a peripheral area surrounding the display area, wherein one of the first metal layer and the second metal layer comprises an external trace located in the peripheral area, and the shielding pattern layer overlaps the external trace on the normal line of the substrate.

19. The display device of claim 10, wherein a material of the shielding pattern layer and the channel layers comprises a semiconductor material.
